(19) United States
(12) Patent Application Publication
(10) Pub. No.: US 2020/0259029 A1
(43) Pub. Date: Aug. 13, 2020

(54) Photovoltaic module having scattering patterns

(71) Applicant: Nederlandse Organisatie voor toegepast-natuurwetenschappelijk Onderzoek TNO, The Hague (NL)

(72) Inventor: Evert Eugène Bende, Petten (NL)

(73) Assignee: Nederlandse Organisatie voor toegepast-natuurwetenschappelijk Onderzoek TNO, The Hague (NL)

(21) Appl. No.: 16/647,041

(22) PCT Filed: Sep. 21, 2018
(86) PCT No.: PCT/NL2018/050625

§ 371 Date: Mar. 13, 2020

(30) Foreign Application Priority Data
Sep. 26, 2017 (NL) 2019628

(51) Int. Cl. H01L 31/054; H01L 31/048; H01L 31/05; H01L 31/18

(52) U.S. Cl. CPC H01L 31/054; H01L 31/18; H01L 31/0504; H01L 31/048

(57) ABSTRACT

A photovoltaic module (1) having photovoltaic cells (2) positioned in a space between a front and a back sheet (4, 5). A scattering layer (7) is present having a radiation scattering pattern with first and/or second surface areas (7a, 7b), in combination with third surface areas (7c). The first surface areas (7a) are aligned above ribbons (3), and the second surface areas (7b) with spaces between adjacent photovoltaic cells (2). The third surface areas (7c) are aligned with a perimeter surface area of the photovoltaic module (1) outside of a surface area formed by the photovoltaic cells (2). The scattering layer (7) comprises a plurality of strips and a plurality of interruptions (8) between one or more of the plurality of strips. Furthermore, a method for assembling a photovoltaic module (1) comprises printing the radiation scattering pattern on a surface of the front sheet (4) and/or back sheet (5).

### FIELD OF THE INVENTION

The present invention relates to a photovoltaic module having one or more photovoltaic cells, the one or more of photovoltaic cells being positioned in a space between a front sheet and a back sheet, the space further comprising an encapsulant material. In a further aspect, the present invention relates to a method for assembling a photovoltaic module according to any one of the present invention embodiments.

### BACKGROUND ART

US patent publication US2007/0125415 discloses crystalline silicon photovoltaic modules with an improved efficiency. Typically in photovoltaic modules tinned flat copper wire is used to increase the conductivity of a bus bar metallization and to interconnect to adjacent cells. In this publication, embodiments are disclosed wherein a flat bus wire is patterned with shallow v-shaped grooves using metal forming techniques, such as rolling, stamping and drawing. The grooves are designed so that incident light is reflected up toward the glass superstrate of the module at an internal interface angle that is large enough so that the light undergoes total internal reflection at the glass-air interface and is reflected onto the solar cell.

International patent publication WO2008/147209 discloses a reflective structure applied to areas of a photovoltaic module between adjacent photovoltaic cells. A liquid polymer is applied in the area between photovoltaic cells, cured into a V-shaped structure and covered by a reflecting layer. The resulting reflecting V-shaped layer allows light incident on the area between photovoltaic cells to be (internally) reflected and (partially) converted into electrical energy by the photovoltaic cells.

International patent publication WO2011/082806 discloses a solar cell module with a base having photovoltaic active zones and inactive zones, and at least one diffractive element arranged above one of the inactive zones. Multiple examples are disclosed where the diffractive element is present, e.g. on top of connecting elements, between individual cells and on the outside rim of the PV module. A combination of diffraction and internal PV module reflection eventually ensures more impinging light is reaching the active areas.

European patent publication EP-A-2 897 179 discloses a solar cell module having a first reflector RF1 in a first space between a plurality of solar cells of a string, and a second reflector RF2 positioned a second space between strings. In the embodiment shown in FIG. 11 also further reflectors RF3 (between RF1 and RF2 reflectors) and reflectors RFEn are positioned on outer edges of the PV module.

### SUMMARY OF THE INVENTION

The present invention seeks to provide a photovoltaic module having an improved efficiency, yet can still be easily and economically manufactured.

According to the present invention, a photovoltaic module as defined above is provided, comprising a plurality of ribbons, the plurality of ribbons providing an electrical interconnection of the one or more photovoltaic cells, and a scattering layer having a radiation scattering pattern, the radiation scattering pattern comprising first surface areas and/or second surface areas, in combination with third surface areas. The first surface areas are aligned above the plurality of ribbons on and between individual ones of the one or more photovoltaic cells, the second surface areas being aligned with spaces between adjacent ones of the one or more photovoltaic cells, and the third surface areas aligned with a perimeter surface area of the photovoltaic module outside of a surface area formed by the one or more photovoltaic cells. The scattering layer comprises a plurality of strips and a plurality of interruptions between one or more of the plurality of strips.

The present invention embodiments allow to provide a photovoltaic module having an improved efficiency, as more of the radiation impinging on the photovoltaic module is scattered towards active areas of the photovoltaic module and converted into electrical energy. The interruptions between one or more of the plurality of strips in the scattering layer allow to efficiently manufacture the photovoltaic module by allowing air to escape from between the various layers when laminating the layers together. Unlike the prior art photovoltaic modules using V-shaped reflectors on top of ribbons that are optimized for light that perpendicularly impinges on the glass surface, the present invention embodiments are efficient for arbitrary angles of incidence.

In a further aspect, the present invention relates to a method as defined above, the method comprising printing the radiation scattering pattern on a surface of the front sheet and/or back sheet using an ink or a screen print material (such as a paste) with an inorganic or organic binder material, and laminating the back sheet, the one or more photovoltaic cells, the encapsulant material, and the front sheet. As compared to conventional assembly methods for photovoltaic modules, only a very simple additional step is needed to provide the enhanced efficiency.

### SHORT DESCRIPTION OF DRAWINGS

The present invention will be discussed in more detail below, with reference to the attached drawings, in which

FIG. 1 shows a partial cross sectional view of a photovoltaic module according to an embodiment of the present invention;

FIG. 2 shows a top view of a photovoltaic module according to a further embodiment of the present invention, having a 6×10 photovoltaic cell layout;

FIG. 3 shows a top view of a photovoltaic module according to an even further embodiment of the present invention, having a 1×2 photovoltaic cell layout;

FIG. 4 shows a top view of a photovoltaic module according to an alternative embodiment of the FIG. 3 embodiment; and

FIG. 5 shows a top view of a photovoltaic module according to an even further embodiment of the present invention.

### DESCRIPTION OF EMBODIMENTS

Photovoltaic modules having one or more photovoltaic cells are widely used nowadays, and the further integration in buildings and living areas continues to drive efforts to obtain more efficient photovoltaic modules.

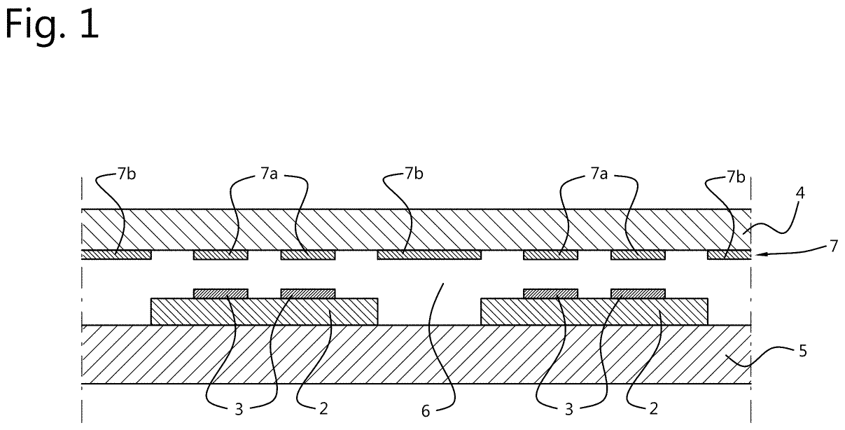

FIG. 1 shows a partial cross sectional view of a layered structure of a photovoltaic module 1, comprising (from bottom to top) a back sheet 5, an encapsulant layer comprising an encapsulant material 6 wherein the one or more photovoltaic cells 2 are embedded, and a front sheet 4. Alternatively, the one or more photovoltaic cells 2 may be sandwiched between two encapsulant material layers, which after laminating the stack of layers into the photovoltaic module 1 from the encapsulant layer. Each photovoltaic cell 2 is provided with busbars on top for collecting charge carriers from the photovoltaic cell 2, as well as with ribbons 3 (or tabs) which interconnect adjacent ones of the one or more photovoltaic cells 2. In general the ribbons 3 are connected to the busbars using soldering connections/layers. It is noted that in actual implementations, the stack of layers may comprise even further layers, such as an anti-reflection coating (ARC) layer (e.g. on top of the front sheet 4). Also photovoltaic modules 1 are known which are using bifacial photovoltaic cells 2, which are then provided with a further encapsulant layer between the lower side of the photovoltaic cells 2 and the back sheet 5.

The present invention embodiments enhance efficiency of the photovoltaic module 1 by utilizing a scattering layer 7 having a radiation scattering pattern, allowing to use more of the (light) radiation impinging on a surface of the photovoltaic module for conversion into electrical energy by the photovoltaic cells 2. In the specific embodiment as shown in FIG. 1, first surface areas 7a are shown, which are aligned with the ribbons 3 on/between photovoltaic cells 2, as well as second surface areas 7b, which are aligned with spaces between individual photovoltaic cells 2 (i.e. inter-cell areas). In further embodiments, third surface areas 7c are also provided as part of the scattering layer 7, which are aligned with a part of the photovoltaic module surface outside of the one or more photovoltaic cells 2.

In general, the present invention embodiments relate to a photovoltaic module having one or more photovoltaic cells 2, the one or more of photovoltaic cells 2 being positioned in a space between a front sheet 4 and a back sheet 5, the space further comprising an encapsulant material 6. The photovoltaic module 1 comprises a plurality of ribbons 3, the plurality of ribbons 3 providing an electrical interconnection of the one or more photovoltaic cells 2, and a scattering layer 7 having a radiation scattering pattern. The radiation scattering pattern comprises first surface areas and/or second surface areas, in combination with third surface areas. The first surface areas 7a are aligned above the plurality of ribbons 3 on and between individual ones of the one or more photovoltaic cells 2, the second surface areas 7b are aligned with spaces between adjacent ones of the one or more photovoltaic cells 2. The third surface areas 7c are aligned with a perimeter surface area of the photovoltaic module 1 outside of a surface area formed by the one or more photovoltaic cells 2. The perimeter surface area of the photovoltaic module 1 is the front (or back) surface edge area of the photovoltaic module 1 where no photovoltaic cells 2 are present.

This results in a scattering layer 7 which is very effective and is optimized with regard to the effective scattering area by being aligned with areas of the photovoltaic module 1 which are not actively converting radiation into electrical energy. As a result of the scattering action by the radiation scattering pattern, impinging radiation is reflected and/or diffused (e.g. isotropically scattered) in a different direction, and directly or indirectly (via internal reflection, e.g. at the interface between the front sheet 4 and the (air) environment) impinges on active surfaces of the one or more photovoltaic cells 2. The radiation scattering (white) pattern diffuses incoming light towards energy producing portions of the photovoltaic module 1, i.e. the active photovoltaic cell 2 surfaces. The scattering effect of the radiation scattering pattern is based on (internal) reflection, and/or diffusion away from areas of photovoltaic module 1 which are not effective in producing electrical energy.

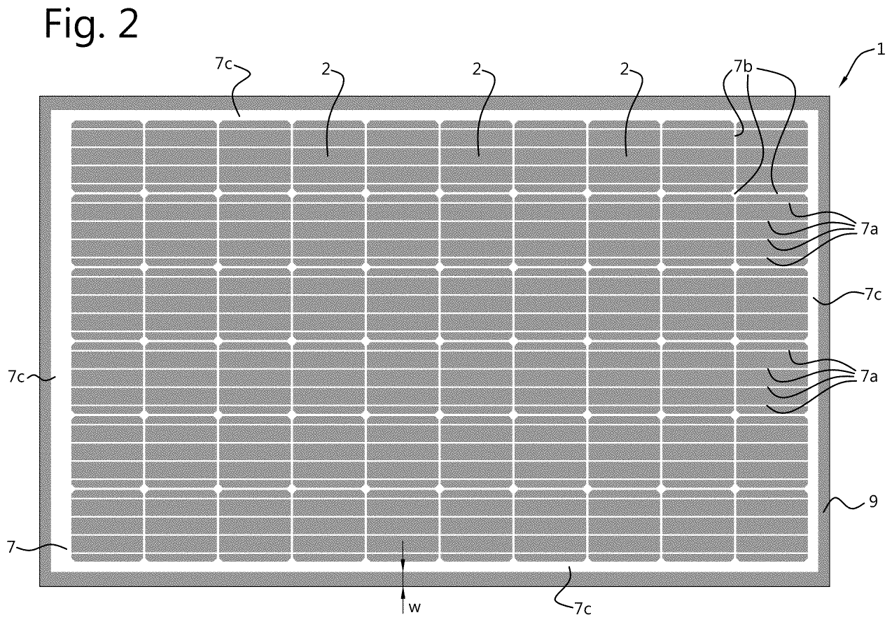

FIG. 2 shows a top view of a photovoltaic module 1 according to a further embodiment of the present invention, having a 6×10 photovoltaic cell 2 layout. In this embodiment, all three types of surface areas 7a-7c as discussed are part of the radiation scattering pattern of the scattering layer 7. Specific for this embodiment is that the third surface areas 7c extend up to a predetermined outer edge surface area 9 of the photovoltaic module 1, thus leaving a strip of the outer edge area of the photovoltaic module 1 free of scattering layer material. This allows a proper lamination process, as a bare circumference is available on the front sheet 4 (and/or back sheet 5) for bonding to the layer of encapsulant material 6. The width of the predetermined outer edge surface area 9 is indicated by win FIG. 2, and is e.g. between 3 mm and 30 mm.

In a further embodiment of the present invention, the third surface areas comprise at least a surface area of the photovoltaic module above bussings electrically interconnecting strings of one or more of the plurality of photovoltaic cells. Such bussings are usually present on one side of the photovoltaic module 1, e.g. on one of the short sides of a photovoltaic module 1. This is the case as well in the embodiment shown in FIG. 2, where the left side third surface area 7c is wider than the third surface areas 7c on the to, right and lower side of the photovoltaic module 1 as shown. In even further embodiments (e.g. in a symmetric photovoltaic module 1 using half size photovoltaic cells 2), the bussings may also be present in the middle of the photovoltaic module 1 between two mirrored groups of photovoltaic cells, and then one of the second surface areas 7b (inter-cell areas) may be widened to cover all the non-active photovoltaic module areas associated with the bussings.

In order to provide embodiments of the photovoltaic module 1 having an enhanced efficiency, the radiation scattering pattern is (at least partially) reflective, e.g. by having a white color. This ensures that radiation which can be converted into electrical energy by the one or more photovoltaic cells 2 (in general in a wavelength range from 300-1100 nm) is scattered from an inactive area to active areas of photovoltaic cells 2.

In further embodiments, the radiation scattering pattern comprises a radiation scattering material, e.g. a white pigment, which is an effective radiation scattering material. The radiation scattering material comprises one or more of the group of: diatomaceous earth; silica; calcium carbonate; barytes; clay; magnesium silicate; lithopone; zinc oxide; antimony oxide; zinc sulphide; titanium dioxide (anatase); titanium dioxide (rutile); and talc. To further enhance the reflective and scattering properties of the radiation scattering pattern, in a further embodiment, the radiation scattering pattern may be formed from glass frit in addition to the radiation scattering material, wherein the glass frit is melted to form a matrix structure with the radiation scattering material included.

In a further aspect, the present invention relates to a method for assembling a photovoltaic module 1 according to any one of the embodiments described herein, the method comprising printing the radiation scattering pattern on a surface of the front sheet 4 and/or back sheet 5 using an ink, a screen print material (e.g. a paste) with inorganic or organic binder material, and laminating the back sheet 5, the one or more photovoltaic cells 2, the encapsulant material 6 (in one or two layers), and the front sheet 4. This means that only a very simple additional step is needed to provide the enhanced efficiency in photovoltaic modules 1 of the present invention.

Processes that can be used to apply the radiation scattering pattern to the front sheet 4 and/or back sheet 5 include but are not limited to ink-jet printing, screen printing, stencilling; roller printing, tampon printing, pad printing; powder coating; laser sintering, thermal printing.

The production of a photovoltaic module 1 according to one of the embodiments described herein, may comprise various steps, even at different locations. E.g. in a first type of module factory, the following subsequent steps are implemented: Glass (front sheet 4) washing; Organic ink/paste screen print on the front sheet 4 (e.g. glass); Curing at elevated temperature (e.g. 200° C.) or UV curing; Stacking/storage/transport in factory. In a second type of module factory, the following steps are executed: Glass washing; Organic ink/paste screen print on the front sheet 4 (e.g. glass); Pre-curing at typically 50-250° C. or UV pre-curing; Stacking/storage/transport in factory; Realizing final cure of the paste during lamination-curing process with typical conditions that apply to lamination, i.e. a heating step of 110-120° C. for 4˜10 min; Curing at 140-150° C. for ˜6 to 30 min (depending on encapsulant material 6 formulation and process).

It is noted that in the method embodiments described, the ink or screen print paste could comprise organic material, such as (poly-) ethylene-co-vinyl acetate (EVA); polyvinyl butyral (PVB); ionomer; polyethylene/polyoctene copolymer (PO); thermoplastic polyurethane (TPU); poly(dimethylsiloxane) (PDMS); poly(diphenyl dimethyl siloxane) (PDPDMS); poly(phenyl-methyl siloxane) (PPMS); Silicone/PU hybrid; PMMA or inorganic material: such as Glass frits/enamel printing.

The scattering layer may be provided on an inner surface of the front sheet 4, as shown in the partial cross sectional view of FIG. 1, i.e. in contact with the encapsulant material 6. Alternatively, or additionally, the scattering layer may be provided on an inner surface of the back sheet 5. In the latter case, the one or more photovoltaic cells 2 may be bifacial photovoltaic cells 2. Thus, the present invention features may be applied in various types of photovoltaic modules 1:
a photovoltaic module 1 having a transparent (glass) front sheet 4, monofacial photovoltaic cells 2 and a white back sheet 5 (note that the radiation scattering pattern may be from a material with better reflective properties than the back sheet 5);
a photovoltaic module 1 having a transparent (glass) front sheet 4, a transparent (glass) back sheet 5, and either bifacial or monofacial photovoltaic cells 2.

When using bifacial photovoltaic cells 2, a benefit is the additional energy yield due to rear illumination. The most likely application of this is in the field of commercial or utility scale photovoltaic power plants and on flat roofs where systems can utilize the albedo effect of roof reflection, e.g. on factory roofs. Even when using monofacial photovoltaic cells 2, enhanced efficiency is obtained, and when applying these in glass-glass configurations, the added benefit is obtained of enhanced longevity.

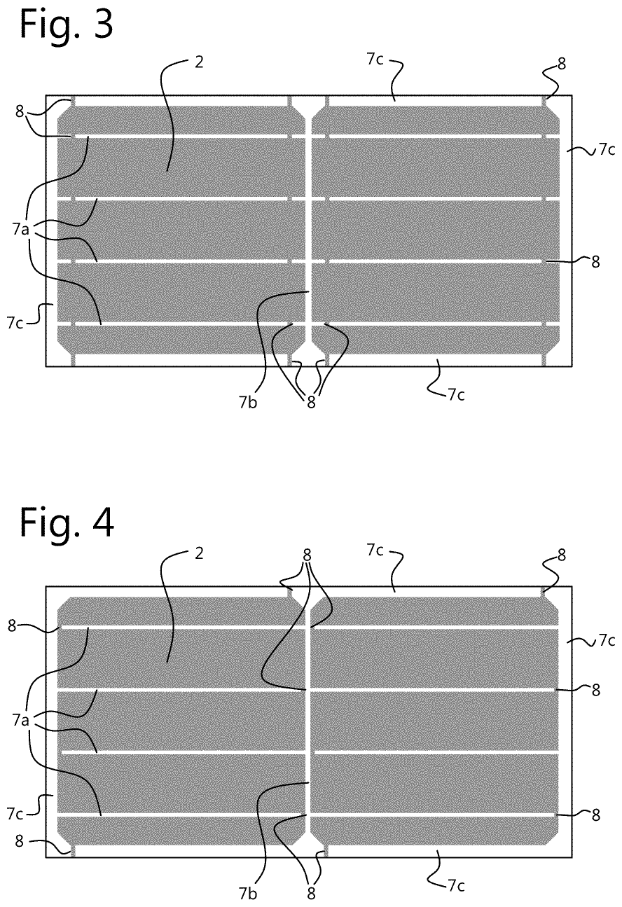

In a further group of embodiments, a photovoltaic module 1 is provided wherein the scattering layer 7 comprises a plurality of (rectangular) strips and a plurality of interruptions 8 between one or more of the plurality of strips. In a further embodiment each of the plurality of interruptions 8 have a dimension smaller than a maximum width of the associated strips. FIG. 3 shows a top view of a photovoltaic module 1 according to this embodiment. Here, the photovoltaic module has a 1×2 photovoltaic cell layout, and the FIG. 3 embodiment shows the photovoltaic cells 2 as well as the first, second, and third surface areas 7a-c of the scattering layer 7. As for the photovoltaic module 1 embodiments described above, the combined application of reflection areas in between photovoltaic cells 2 (second surface areas 7b, above tabs/ribbons 3 (first surface areas 7a) and (on top of bussing) at the edges (third surface areas 7c) of the photovoltaic module 1, ensures an enhanced efficiency.

The interruptions 8 have the effect that air from any point in the photovoltaic module 1 can flow towards the edges of the photovoltaic module 1, and this allows air evacuation during lamination from sides of the stack of layers forming the photovoltaic module 1. When the interruptions 8 have a dimension smaller than a maximum width of the associated strips, a small as possible loss by not having the radiation scattering pattern extending at those locations is obtained. This may also be implemented by having the interruptions 8 being directed perpendicular to a length direction of the strip.

In other words, the plurality of interruptions 8 provide an (air) access path from a side of the scattering layer 7 to all surface areas outside of the first, second and third surface areas 7a-c, i.e. to the non-occupied areas of the radiation scattering pattern. In an even further embodiment, one or more of the plurality of interruptions 8 is provided near to two adjacent and differently oriented strips, and e.g. closer to the wider strips, as there will be more possible space entrapping air at such locations (see the embodiment shown in FIG. 3). In the alternative embodiment shown in FIG. 4, the interruptions 8 have alternating positions in the strips, which make the interruptions 8 less visible to a human eye. Furthermore, the alternating interruptions 8 in this embodiment provide for a meandering air access path from a side of the scattering layer 7 to all surface areas of the front sheet 4 outside of the first, second and third surface areas 7a-c.

Alternatively, or for a specific sub-group of interruptions 8, the dimensions of the interruptions 8 have a dimension larger than a maximum width of the associated strips. This will allow to locally obtain a proper bonding between the encapsulant material 6 and the front (glass) sheet 4.

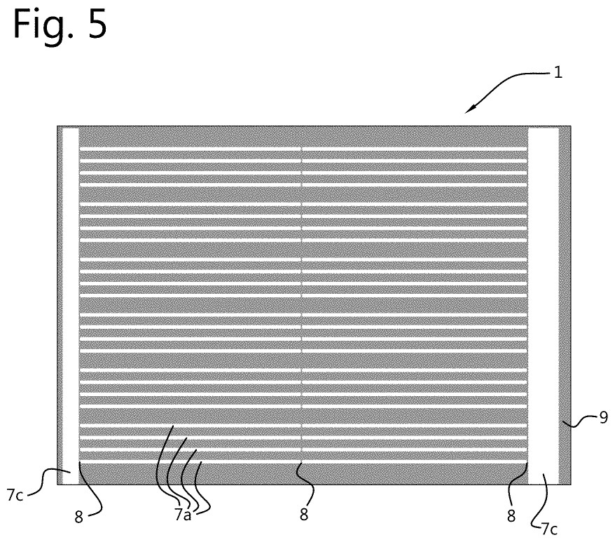

FIG. 5 shows a top view of a photovoltaic module 1 according to an even further embodiment of the present invention, wherein the radiation scattering pattern comprises a combination of first and third surface areas 7b, 7c. This can be an embodiment of a photovoltaic module 1 having only a single photovoltaic cell 2, or having multiple photovoltaic cells 2, wherein the ribbons 3 are only applied in a parallel manner. As described above with reference to the embodiment shown in FIG. 2, one of the third surface areas 7c (the right one in the embodiment shown in FIG. 5) is wider in order to cover the underlying multiple bussings on one (short) end of the photovoltaic module 1 (usually where a junction box is also present for external connection of the photovoltaic module 1). Furthermore, in this embodiment, interruptions 8 are provided in the middle of the strips formed by the first surface areas 7c, and at the end of these strips close to the third surface areas 7c.

This group of embodiments solve the problem occurring when during the vacuum stage of the photovoltaic module 1 lamination process, the encapsulation material 6 (e.g. EVA) contacts the surface of the front sheet 4 (e.g. a glass plate) on which the (white) radiation scattering pattern is printed, as a result of which air might be included in between the top sheet 4, the radiation scattering pattern and the encapsulant material 6. This is a problem because it leads to a bad appearance, reduced light coupling into the photovoltaic module 1, and thus lower power output. Further, this introduces an increased chance of corrosion of the metal parts of the photovoltaic module 1 due to the presence of oxygen and humidity during use.

In general, the method embodiments comprise the additional step of evacuating air from a side of the photovoltaic module 1, more specifically from between the front and/or back sheet 4, 5 and the encapsulant material 6, i.e. where scattering layer 7 is present.

The mentioned problem may also be solved using an even further method embodiment, wherein the photovoltaic module 1 further comprises an encapsulant layer having perforations. The perforation may be aligned with non-printed surface areas of the radiation scattering pattern. The encapsulant layer with perforations may be positioned between the front/back sheet 4, 5 and the one or more photovoltaic cells 2 as described in relation to the embodiments above.

The present invention has been described above with reference to a number of exemplary embodiments as shown in the drawings. Modifications and alternative implementations of some parts or elements are possible, and are included in the scope of protection as defined in the appended claims.

1. A photovoltaic module having one or more photovoltaic cells,
the one or more of photovoltaic cells being positioned in a space between a front sheet and a back sheet, the space further comprising an encapsulant material,
the photovoltaic module comprising
a plurality of ribbons, the plurality of ribbons providing an electrical interconnection of the one or more photovoltaic cells, and
a scattering layer having a radiation scattering pattern, the radiation scattering pattern comprising first surface areas and/or second surface areas, in combination with third surface areas,
the first surface areas being aligned above the plurality of ribbons on and between individual ones of the one or more photovoltaic cells,
the second surface areas being aligned with spaces between adjacent ones of the one or more photovoltaic cells, and
the third surface areas aligned with a perimeter surface area of the photovoltaic module outside of a surface area formed by the one or more photovoltaic cells,
wherein the scattering layer comprises a plurality of strips and a plurality of interruptions between one or more of the plurality of strips.

2. The photovoltaic module according to claim 1, wherein the third surface areas extend up to a predetermined outer edge surface area of the photovoltaic module.

3. The photovoltaic module according to claim 2, wherein the predetermined outer edge surface area has a width of between 3 mm and 30 mm.

4. The photovoltaic module according to claim 1, wherein the third surface areas comprise at least a surface area of the photovoltaic module above bussings electrically interconnecting strings of one or more of the plurality of photovoltaic cells.

5. The photovoltaic module according to claim 1, wherein each of the plurality of interruptions have a dimension smaller than a maximum width of the associated strips.

6. The photovoltaic module according to claim 5, wherein the plurality of interruptions (8) provide an access path from a side of the scattering layer (7) to all surface areas outside of the first, second and third surface areas (7a-c).

7. The photovoltaic module according to claim 5, wherein one or more of the plurality of interruptions are provided near to two adjacent and differently oriented strips

8. The photovoltaic module according to claim 1, wherein the radiation scattering pattern is reflective.

9. The photovoltaic module according to claim 1, wherein the radiation scattering pattern comprises a radiation scattering material, e.g. a white pigment.

10. The photovoltaic module according to claim 9, wherein the radiation scattering material comprises one or more of the group of:
diatomaceous earth; silica; calcium carbonate; barytes; clay; magnesium silicate; lithopone; zinc oxide; antimony oxide; zinc sulphide; titanium dioxide (anatase); titanium dioxide (rutile); and talc.

11. The photovoltaic module according to claim 1, wherein the scattering layer is provided on an inner surface of the front sheet.

12. The photovoltaic module according to claim 1, wherein the scattering layer (7) is provided on an inner surface of the back sheet (5).

13. The photovoltaic module according to claim 1, wherein the one or more photovoltaic cells are bifacial photovoltaic cells.

14. A method for assembling a photovoltaic module according to claim 1, the method comprising:
printing the radiation scattering pattern on a surface of the front sheet and/or back sheet using an ink or a screen print material with an inorganic or organic binder material, and
laminating the back sheet, the one or more photovoltaic cells, the encapsulant material, and the front sheet.

15. The method according to claim 14, wherein printing the radiation scattering pattern comprises ink-jet printing, screen printing, stencilling; roller printing, tampon printing, pad printing; powder coating; laser sintering, and thermal printing.

16. The method according to claim 14, further comprising evacuating air from a side of the photovoltaic module.

17. The method according to claim 14, the photovoltaic module further comprising an additional encapsulant layer having perforations.
